(19) United States
(12) Patent Application Publication
(10) Pub. No.: US 2010/0230692 A1
(43) Pub. Date: Sep. 16, 2010

(54) LAMP AND PRODUCTION METHOD OF LAMP

(75) Inventor: Takaki Yasuda, Chiba-shi (JP)

Correspondence Address: SUGHRUE MION, PLLC, 2100 PENNSYLVANIA AVENUE, N.W., SUITE 800, WASHINGTON, DC, 20037, US

(73) Assignee: SHowa Denko K.K., Minato-ku Tokyo (JP)

(21) Appl. No.: 12/304,096

(22) PCT Filed: May 9, 2008
(86) PCT No.: PCT/JP2008/058652

§ 371 Date: Dec. 9, 2008

(30) Foreign Application Priority Data
May 9, 2007 (JP) 2007 124618

(51) Int. Cl. H01L 33/48; H01L 33/58

(52) U.S. Cl. 257/98; 438/26; 257/E33.056; 257/E33.067

(57) ABSTRACT

The present invention provides a lamp comprising a substrate composed of a base substrate and a covering member which are made of an inorganic insulator and are joined through a joining metal layer; and a semiconductor light emitting device mounted on said substrate, wherein a concave portion is provided in a covering member-side surface of said substrate, said semiconductor light emitting device is accommodated in said concave portion, an end face of said metal layer is positioned on a region of the lateral surface of said concave portion which faces said semiconductor light emitting device, and a light reflection portion, which reflects light emitted from said semiconductor light emitting device, is composed of said end face.

This application is the U.S. national phase of International Application No. PCT/JP2008/058652 filed May 9, 2008 which designated the U.S. and claims priority to Japanese Patent Application No. 2007-124618, filed May 9, 2007, the content of which is incorporated herein by reference.

### TECHNICAL FIELD

The present invention relates to a lamp and a production method of a lamp.

### BACKGROUND ART

Conventionally, a lamp comprising a light emitting diode as a light source has been developed as a substitute for various electric bulbs, discharge tubes, and the like. Such a light emitting diode can provide a large volume of light emission per power consumption and causes less failure. Therefore, it has been widely considered as a light source not only for domestic use but also for automobiles.

For example, Japanese Patent Application No. 2005-364388 has disclosed a light emitting diode lamp (lighting device) schematically comprising a plurality of light emitting diodes, a mounting board on which these light emitting diodes are mounted, and a cover plate. A schematic cross-sectional view of this lamp is shown in FIG. 10. As shown in FIG. 10, the mounting board 110 of the lamp comprises an aluminum plate 110a, an insulating resin film 110b formed on a surface of the aluminum plate 110a, and a wiring pattern 113 made of a copper foil formed on the insulating resin film 110b. In addition, the cover plate 114 comprises an aluminum plate 114a, and an insulating resin film 110e formed all over a surface of the aluminum plate 114a. Moreover, the cover plate 114 is provided with a through hole 114b for exposing the wiring pattern 113. By superposing the cover plate 114 on the mounting board 110, this through hole 114b serves as a concave portion 114c for exposing the wiring pattern 113. A light emitting diode 101 is accommodated in this concave portion 114c. Furthermore, the concave portion 114c is filled with a phosphor-containing transparent resin 116. White light can be emitted by using a blue light emitting diode as the light emitting diode, and a yellow phosphor as the phosphor to be filled in the concave portion 114c.

Incidentally, in the lamp shown in FIG. 10, an end face of the cover plate-side of the insulating resin film 110e is exposed on the lateral surface of the concave portion 114c, and this end face of the insulating resin film 110e faces the light emitting diode 101. By so doing, a part of blue light emitted from the light emitting diode 101 is irradiated to the insulating resin film 110e. The insulating resin film 110e is made of a high molecular compound and is prone to absorb blue light. Therefore, light emitted from the light emitting diode 101 is partially absorbed into the insulating resin film 110e, which causes a problem in that a designed volume of light emission can not be obtained.

In addition, the amount of the yellow phosphor to be filled in the concave portion 114c is adjusted at an optimum amount with respect to the volume of light emission from the light emitting diode 101. However, if the designed volume of light emission can not be obtained as mentioned above, the balance between the volume of light emission and the amount of the yellow phosphor is disrupted to cause a concern of changing the luminescent color from white into pale yellow.

### DISCLOSURE OF INVENTION

The present invention takes the above situation into consideration with an object of providing: a lamp which includes a light emitting diode accommodated in a concave portion, wherein a designed volume of light emission can be obtained and the balance between the volume of light emission and the amount of a phosphor is appropriate; and a production method thereof.

To achieve the above object, the present invention employs the following constitutions.

[1] A lamp comprising a substrate composed of a base substrate and a covering member which are made of an inorganic insulator and are joined through a joining metal layer; and a semiconductor light emitting device mounted on the substrate, wherein a concave portion is provided in a covering member-side surface of the substrate, the semiconductor light emitting device is accommodated in the concave portion, an end face of the metal layer is positioned on a region of the lateral surface of the concave portion which faces the semiconductor light emitting device, and a light reflection portion, which reflects light emitted from the semiconductor light emitting device, is composed of the end face.

[2] The lamp according to [1], wherein a light reflective metal film is formed on the end face of the metal layer.

[3] The lamp according to [1], wherein a light reflective metal film is formed on the lateral surface of the concave portion including the end face of the metal layer.

[4] The lamp according to any one of [1] to [3], wherein the covering member is provided with a through hole which constitutes the concave portion, a cover-side joining metal foil is formed around the through hole on a base substrate-side surface of the covering member, a base-side joining metal foil to be superposed with the cover-side joining metal foil is formed on the covering member-side surface of the base substrate, and the metal layer is formed by mutually joining the respective joining metal foils.

[5] The lamp according to [4], wherein the base substrate and the covering member are made of aluminum oxide, and the respective joining metal foils are made of copper.

[6] The lamp according to any one of [1] to [5], wherein a phosphor-containing transparent resin is filled in the concave portion.

[7] The lamp according to any one of [1] to [6], wherein the semiconductor light emitting device is a flip-chip type light emitting diode.

[8] A production method of a lamp, comprising a covering member formation step for providing a through hole in a tabular inorganic insulator, and forming a cover-side joining metal foil around the through hole on a surface of the inorganic insulator; a base substrate formation step for forming a base-side joining metal foil to be superposed with the cover-side joining metal foil, on a surface of a base substrate made of an inorganic insulator; a substrate formation step for superposing the covering member on the base substrate and joining them by thermocompression bonding, to thereby close an opening at one end of the through hole by the base substrate to form a concave portion, as well as forming a metal layer by mutually joining the respective joining metal foils, and disposing an end face of this metal layer on the lateral surface of the concave portion to serve as a light reflection portion; and a mounting step for accommodating a semiconductor light emitting device in the concave portion while arranging the light emitting device to face the light reflection portion.

[9] The production method of a lamp according to [8], wherein the thermocompression bonding is performed by heating the base substrate and the covering member to 1000° C. or higher, in the substrate formation step.

[10] The production method of a lamp according to [8], wherein a light reflective metal film is formed on at least an end face of the metal layer, after the substrate formation step.

According to the lamp of the present invention, the end face of the metal layer is positioned on a region of the lateral surface of the concave portion which faces the semiconductor light emitting device to thereby constitute the light reflection portion. Therefore light emitted from the semiconductor light emitting device will not be partially absorbed, and as a result the volume of light emission from the lamp can be increased.

In addition, according to the lamp of the present invention, the base substrate and the covering member are respectively made of an inorganic insulator, and thereby a majority of the inner surface including the lateral surface of the concave portion is made of the inorganic insulator. Therefore, light emitted from the semiconductor light emitting device will not be absorbed, and the volume of light emission from the lamp can be increased.

Moreover, according to the lamp of the present invention, the light reflective metal film is formed on the end face of the metal layer or the lateral surface of the concave portion including this end face. Therefore, light emitted from the semiconductor light emitting device can be efficiently ejected.

Furthermore, according to the lamp of the present invention, the base substrate and the covering member are mutually joined by mutually joining the respective joining metal foils. Therefore, there is no need of joining the base substrate and the covering member with a fastener or an adhesive, and a lamp which excels in vibration resistance and heat resistance can be produced.

Moreover, according to the lamp of the present invention, a phosphor-containing transparent resin is filled in the concave portion. Therefore, white light can be emitted by, for example, forming the semiconductor light emitting device with a blue light emitting diode, and forming the phosphor with a yellow phosphor.

In addition, according to the production method of a lamp of the present invention, the light reflection portion is formed by superposing the covering member on the base substrate, and by mutually joining the base-side joining metal foil and the cover-side joining metal foil. Therefore, a lamp can be produced without concern of partial absorption of light emitted from the semiconductor light emitting device.

### BRIEF DESCRIPTION OF DRAWINGS

FIG. 1 is a schematic plan view showing a lamp of a first embodiment of the present invention.

FIG. 2 is a schematic cross-sectional view taken along the line A-A′ of FIG. 1.

FIG. 3 is an enlarged schematic cross-sectional view of FIG. 2.

FIG. 4A is a schematic cross-sectional view showing a covering member formation step in a production method of a lamp being an embodiment of the present invention.

FIG. 4B is a schematic cross-sectional view showing a base substrate formation step in the production method of a lamp being an embodiment of the present invention.

FIG. 4C is a schematic cross-sectional view showing a substrate formation step in the production method of a lamp being an embodiment of the present invention.

FIG. 4D is a schematic cross-sectional view showing a mounting step in the production method of a lamp being an embodiment of the present invention.

FIG. 5 is a schematic cross-sectional view showing the principal part of a lamp of a second embodiment of the present invention.

FIG. 6 is a schematic cross-sectional view showing a lamp of a third embodiment of the present invention.

FIG. 7 is an enlarged schematic cross-sectional view of FIG. 6.

FIG. 8A is a schematic cross-sectional view showing a lamp of a fourth embodiment of the present invention.

FIG. 8B is a schematic cross-sectional view showing the principal part of the lamp of the fourth embodiment of the present invention.

FIG. 9A is a schematic cross-sectional view showing a lamp of a fifth embodiment of the present invention.

FIG. 9B is a schematic cross-sectional view showing the principal part of the lamp of the fifth embodiment of the present invention.

FIG. 10 is schematic cross-sectional view showing a conventional lamp.

### DESCRIPTION OF THE REFERENCE SYMBOLS

1, 11, 41, 51, and 61: Lamp, 2: Base board (Base substrate), 3: Covering member, 4: Concave portion, 4b: Lateral surface portion (Lateral surface), 4c: Phosphor-containing transparent resin, 5: Substrate, 5a: Covering member-side surface of substrate, 6: Light emitting device (Semiconductor light emitting device), 8: Joining metal layer, 8a: End face, 9: Light reflection portion, 12 and 42: Light reflective metal film, 21b: Covering member-side surface of base substrate, 31b: Base substrate-side surface of covering member, 33: Through hole, 33a: Opening at one end of through hole, 81: Base-side joining metal foil, 82: Cover-side joining metal foil

### BEST MODE FOR CARRYING OUT THE INVENTION

### First Embodiment

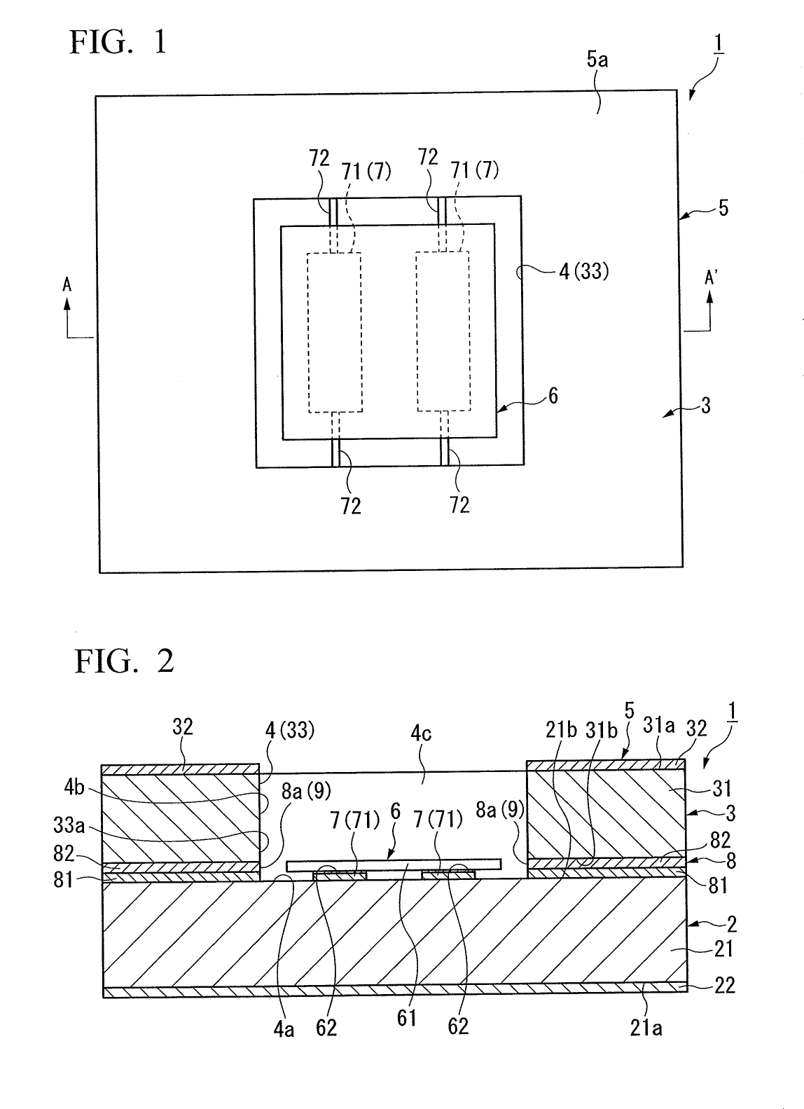

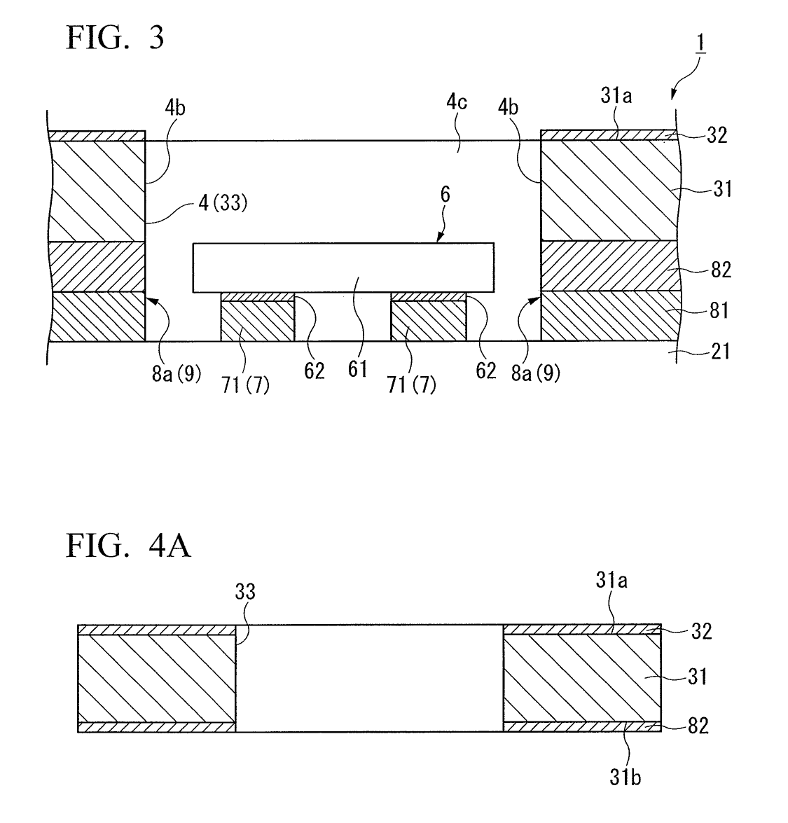

Hereunder is a description of a first embodiment of the present invention, with reference to the drawings. FIG. 1 is a schematic plan view showing a lamp of the present embodiment. FIG. 2 is a schematic cross-sectional view taken along the line A-A′ of FIG. 1. FIG. 3 is an enlarged schematic cross-sectional view of FIG. 2. These drawings are for explanatory purposes only, with respect to the constitution of the lamp of the present embodiment. The size, thickness, dimension, and so forth of the illustrated components may not reflect the actual dimensional relations of the lamp.

As shown in FIG. 1 to FIG. 3, the lamp 1 of the present embodiment schematically comprises a substrate 5 which is integrally composed of a base board (base substrate) 2 and a covering member 3; and a semiconductor light emitting device 6 (hereunder referred to as a light emitting device). The base board 2 and the covering member 3 are integrated through a metal layer 8. In addition, a concave portion 4 is provided in the substrate 5, and a light emitting device 6 is accommodated in this concave portion 4. Moreover, as shown in FIG. 1 to FIG. 3, the base board 2 is exposed on the bottom face of the concave portion 4, and on this exposed base board 2 is formed a pair of wiring patterns 7 made of a copper foil or the like. On these wiring patterns 7 is mounted the light emitting device 6. Furthermore, in the concave portion 4 is positioned an end face 8a of the metal layer 8 which mutually joins the base board 2 and the covering member 3. This end face 8a serves as a light reflection portion 9. The metal layer 8 in FIG. 2 is formed all over the entire surface except for the concave portion 4, however the present invention is not limited thereto. The metal layer 8 may also be formed exclusively around the concave portion 4, with or without patterning of other portions to a degree not to degrade the bonding strength between the base board 2 and the covering member 3.

As shown in FIG. 2 and FIG. 3, the base board 2 which constitutes the substrate 5 comprises a tabular board main body 21 made of an inorganic insulator such as alumina or aluminum nitride; the wiring patterns 7 which are made of a metal foil and are formed on the board main body 21; a joining metal foil 81 which is made of a metal foil, is formed on the board main body 21, and constitutes the metal layer 8; and a warpage prevention metal foil 22 which is made of copper or the like and is formed all over a surface 21a of the board main body 21 which is the opposite side to the wiring pattern 7 side. The warpage prevention metal foil 22 is to prevent warping caused by the difference in the coefficient of thermal expansion between the board main body 21, the wiring patterns 7, and the joining metal foil 81. The thickness thereof is set at about 35 to 250 μm. In addition, metal foils for respectively forming the wiring patterns 7, the joining metal foil 81, and the warpage prevention metal foil 22 are preferably the same metal species in the same thickness. As a specific example of the base board 2, a printed circuit board can be enumerated.

Similarly to the warpage prevention metal foil 22, the pair of wiring patterns 7 is made of a copper foil or the like in a thickness of about 35 to 250 μm. As shown in FIG. 1, each wiring pattern 7 respectively comprises a terminal portion 71 and wiring portions 72 each connected to the terminal portion 71. As described later, each terminal portion 71 is respectively connected to a positive electrode pad or a negative electrode pad of the light emitting device 6. More desirably, the thickness of the wiring pattern 7 is thinner than the thickness of the joining metal foil 81.

Moreover, similarly to the wiring patterns 7, the base-side joining metal foil 81 formed on the covering member-side surface 21b of the board main body 21 is made of a copper foil or the like in a thickness of about 35 to 250 μm. In FIG. 2, the joining metal foil 81 is formed almost all over the entire surface of a region of the covering member-side surface 21b of the board main body 21 to be superposed with the covering member 3. It is not necessary to form the joining metal foil 81 all over the entire surface of the base board 2 except for the concave portion 4. The joining metal foil 81 may also be formed exclusively around the concave portion 4, with or without patterning to a degree not to degrade the bonding strength between the base board 2 and the covering member 3.

The relation between the wiring patterns 7 and the joining metal foil 81 may take any form as long as the wiring patterns 7 and the joining metal foil 81 are mutually unconnected and the joining metal foil 81 is independent from the wiring pattern 7. Moreover, the relation may also be such that the joining metal foil 81 is divided into at least two patterns, in which one pattern is connected to a wiring pattern 7 and the other pattern is connected to the other wiring pattern 7. In short, the relation may take any form unless the pair of wiring patterns 7 is mutually and electrically connected through the joining metal foil 81. It is unfavorable that the respective wiring patterns 7 are mutually and electrically connected, since a short-circuit may occur.

Next, as shown in FIG. 1 to FIG. 3, the covering member 3 comprises a tabular board main body 31 (tabular insulator) made of an insulating material such as alumina; and a warpage prevention metal foil 32 which is made of copper or the like and is formed all over a surface 31a of the board main body 31 which is the opposite side to the base board 2. Similarly to the metal foil 22 of the base board 2, the warpage prevention metal foil 32 has a thickness of about 35 to 250 μm, and prevents warping caused by the difference in the coefficient of thermal expansion between the board main body 31 and the joining metal foil 82 that will be described later.

In addition, a through hole 33 is provided in the board main body 31. Furthermore, the cover-side joining metal foil 82 is formed in a region of a base board-side surface 31b of the board main body 31 which encloses the through hole 33. Similarly to the base-side joining metal foil 81, this cover-side joining metal foil 82 is made of a copper foil or the like in a thickness of about 35 to 250 μm, and is formed in a shape approximately the same as that of the base-side joining metal foil 81. That is, the joining metal foil 82 may be formed all over the entire surface except for the through hole 33, or may also be formed exclusively around the through hole 33, with or without patterning to a degree not to degrade the bonding strength between the base board 2 and the covering member 3.

In addition, as shown in FIG. 2 and FIG. 3, the abovementioned base board 2 and covering member 3 integrally compose the substrate 5 which constitutes the lamp 1. In a surface 5a of this substrate 5, the concave portion 4 comprising the through hole 33 is formed. The concave portion 4 is formed by closing an opening at one end 33a of the through hole 33 with the base board 2, and is defined by a bottom face portion 4a composed of the covering member-side surface 21b of the base board 2, and a lateral surface portion 4b composed of faces defining the through hole 33. On this bottom face portion 4a of the concave portion 4, the terminal portions 71 of the wiring patterns 7 is disposed.

Moreover, between the base board 2 and the covering member 3, the base-side joining metal foil 81 and the cover-side joining metal foil 82 are mutually joined by thermocompression bonding, whereby the metal layer 8 is formed between the base board 2 and the covering member 3. Through this metal layer 8, the base board 2 and the covering member 3 are integrated without an adhesive or a fastener. In addition, an end face 8a of the metal layer 8 is positioned on a region of the lateral surface portion 4b of the concave portion 4 which faces the light emitting device 6. This end face 8a constitutes the light reflection portion 9.

Next, the light emitting device 6 is composed of, for example, a flip-chip type blue light emitting diode. This light emitting device 6 schematically comprises a device main body 61 composed of a light emitting layer (not shown); and positive and negative electrode pads 62 provided on the device main body 61. As shown in FIG. 2 and FIG. 3, the light emitting device 6 is accommodated in the concave portion 4, while the electrode pads 62 are respectively connected to the terminal portions 71 of the wiring patterns 7. In the present invention, a so-called face-up type light emitting diode may also be used as the light emitting device.

This light emitting device 6 is mounted on the terminal portions 71 in a thickness approximately the same as that of the base-side joining metal foil 81. Accordingly, the light emitting device 6 is disposed at a height approximately the same as that of the cover-side joining metal foil 82, with respect to the bottom face 4a of the concave portion 4.

In addition, the thickness of the respective electrode pads 62 of the light emitting device 6 is set to about several μm, and the thickness of the device main body 61 is set to about 80 μm. On the other hand, as described above, the thickness of the cover-side joining metal foil 82 is set to about 35 to 250 μm. Due to such a dimensional relation, the end face 8a of the metal layer 8 is positioned on a region of the lateral surface portion 4b of the concave portion 4 which encloses the device main body 61 of the light emitting device 6.

As described above, the end face 8a of the metal layer 8 is positioned on a region of the lateral surface portion 4b of the concave portion 4 which faces the light emitting device 6. This end face 8a serves as the light reflection portion 9 which reflects light emitted from the light emitting device 6. With this light reflection portion 9, light emitted from the light emitting device 6 will not be absorbed, but can be efficiently ejected to the outside of the concave portion 4. Moreover, the lateral surface portion 4b of the concave portion 4 is formed by the through hole 33 provided in the covering member 3, and the bottom face portion 4a of the concave portion 4 is formed by the base board 2. Accordingly, the majority of the bottom face portion 4a and the lateral surface portion 4b of the concave portion 4 are made of an inorganic insulator having a small optical absorptance. Therefore, light emitted from the light emitting device 6 will not be absorbed into the bottom face portion 4a and the lateral surface portion 4b of the concave portion 4, but is efficiently ejected to the outside of the concave portion 4.

Furthermore, a yellow phosphor-containing transparent resin 4c is filled in the concave portion 4. By embedding a blue light emitting diode (light emitting device 6) in this yellow phosphor-containing transparent resin 4c, white light can be emitted due to the additive color effect of light when the blue light emitting diode is lit.

According to the lamp 1 mentioned above, the end face 8a of the metal layer 8 is positioned on the region of the lateral surface 4b of the concave portion 4 which faces the light emitting device 6 to thereby constitute the light reflection portion 9. Therefore, light emitted from the light emitting device 6 will not be partially absorbed, and the volume of light emission from the lamp 1 can be increased.

In addition, the base board 2 and the covering member 3 are respectively made of an inorganic insulator, and thereby a majority of the inner surface including the lateral surface portion 4b of the concave portion 4 is made of the inorganic insulator. Therefore, light emitted from the light emitting device 6 will not be absorbed, and the volume of light emission from the lamp 1 can be further increased.

Furthermore, the base board 2 and the covering member 3 are mutually joined by mutually joining the respective joining metal foils 81 and 82. Therefore, there is no need of joining the base board 2 and the covering member 3 with a fastener or an adhesive, and a lamp 1 which excels in vibration resistance and heat resistance can be produced.

In addition, the phosphor-containing transparent resin 4c is filled in the concave portion 4. Therefore, white light can be emitted by, for example, forming the light emitting device 6 with a blue light emitting diode, and forming the phosphor with a yellow phosphor.

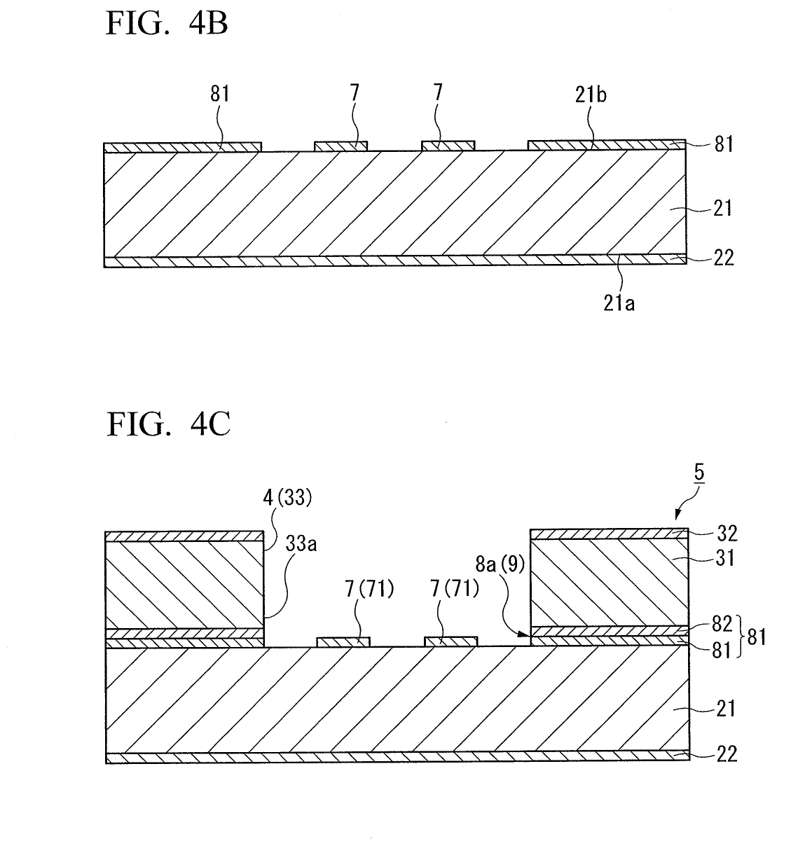

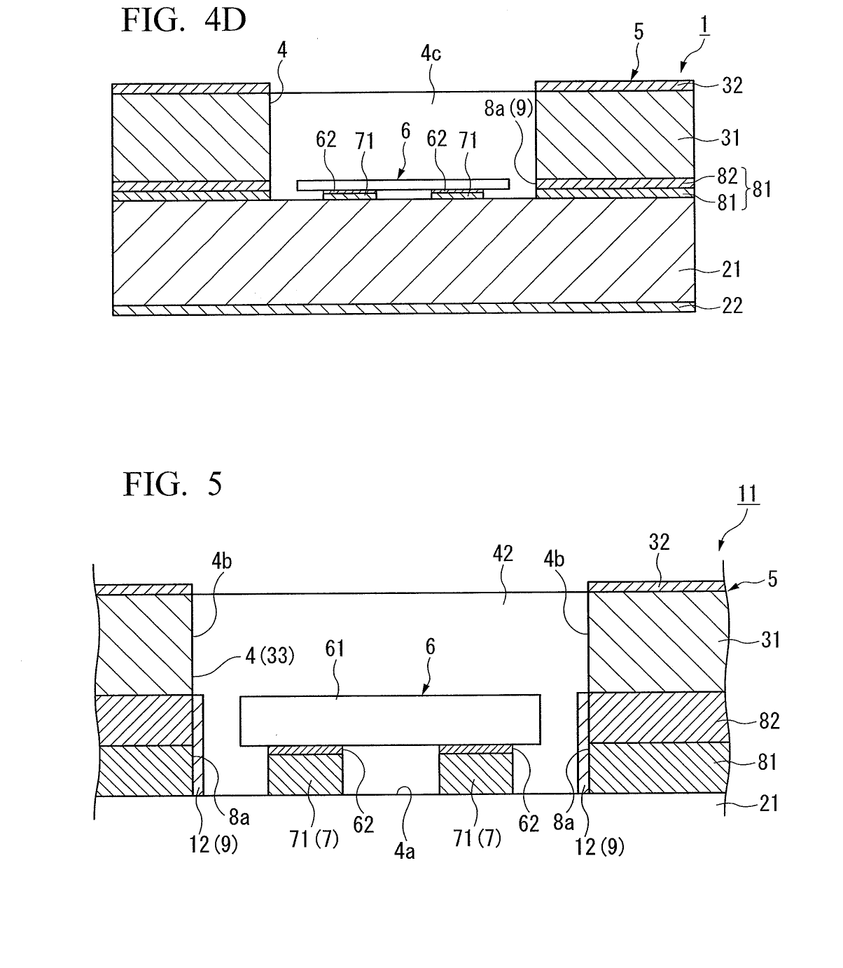

Next is a description of a production method of the lamp 1 mentioned above, with reference to the drawings. FIG. 4 is to explain the production method of a lamp of the present embodiment, in which FIG. 4A is a schematic cross-sectional view showing a covering member formation step, FIG. 4B is a schematic cross-sectional view showing a base substrate formation step, FIG. 4C is a schematic cross-sectional view showing a substrate formation step, and FIG. 4D is a schematic cross-sectional view showing a mounting step.

FIG. 4 is for explanatory purposes only, similarly to FIG. 1 to FIG. 3, with respect to the lamp of the present embodiment. The size, thickness, dimension, and so forth of the illustrated components may not reflect the actual dimensional relations of the lamp.

The production method of the lamp 1 of the present embodiment schematically comprises a covering member formation step, a base board formation step (base substrate formation step), a substrate formation step, and a mounting step. Hereunder, the respective steps are sequentially described.

Firstly, in the covering member formation step, a laminated plate (for example, a printed circuit board) in which a copper foil is laminated all over the opposite surfaces of the board main body 31 of alumina or the like is prepared, and then the copper foil on a surface 31b of the laminated plate is patterned by means of etching or the like, to thereby form the cover-side joining metal foil 82. Moreover, the copper foil on the other surface 31a of the board main body 31 is etched in the same manner, to thereby form the warpage prevention metal foil 32. The joining metal foil 82 may be left all over the entire surface except for the through hole 33, or may also be left exclusively around the through hole 33, with or without patterning to a degree not to degrade the bonding strength between the base board 2 and the covering member 3.

Next, as shown in FIG. 4A, the through hole 33 is formed in the board main body 31 by a laser cut method.

Next, in the base board formation step, similarly to the covering member formation step, a laminated plate (for example, a printed circuit board) in which a copper foil is laminated all over the opposite surfaces of the board main body 21 of alumina or the like is prepared. Then, the copper foil on a surface of the laminated plate is patterned by means of etching or the like, to thereby form the wiring patterns 7 and the joining metal foil 81. The copper foil on the other surface is left as it is. This copper foil serves as the warpage prevention metal foil 22 of the board main body 21. In such a manner, the base board 2 as shown in FIG. 4B is formed. The joining metal foil 81 may be left all over the entire surface except for the region to be superposed with the through hole 33, or may also be left exclusively around the region to be superposed with the through hole 33, with or without patterning to a degree not to degrade the bonding strength between the base board 2 and the covering member 3.

Next, in the substrate formation step, as shown in FIG. 4C, the covering member 3 is superposed on the base board 2, and then joined by thermocompression bonding. The thermocompression bonding is performed by mutually bonding the base board 2 and the covering member 3 with a pressure at about 1.5 kg/cm² to 3 kg/cm² while heating the base board 2 and the covering member 3 to 1000° C. or higher.

By this thermocompression bonding, the opening at one end 33a of the through hole 33 in the covering member 3 is closed by the base board 2 to thereby form the concave portion 4. In this concave portion 4, the terminal portions 71 of the base board 2 are exposed.

Moreover, by this thermocompression bonding, the cover-side joining metal foil 82 and the base-side joining metal foil 81 are joined. These joining metal foils 81 and 82 are both made of copper, and copper oxide is generated on the surface of the copper at a temperature of 1000° C. or higher. The melting point of this copper oxide is lower than that of metal copper. Accordingly, coatings made of copper oxide are formed over the surfaces of the joining metal foils 81 and 82 by heating the joining metal foils 81 and 82 to 1000° C. or higher. These coatings made of copper oxide are melted and fused together so that the joining metal foils 81 and 82 are mutually joined.

The metal layer 8 is formed by joining the respective joining metal foils 81 and 82. Through this metal layer 8, the base board 2 and the covering member 3 are integrated to form the substrate 5.

In addition, the end face 8a of the metal layer 8 is positioned on the lateral surface portion 4b of the concave portion 4. The surface of this end face 8a is a metallic luster surface, and thereby the end face 8a serves as the light reflection portion 9 having a relatively high reflectance of light.

Finally, as shown in FIG. 4D, in the mounting step, the light emitting device 6 is accommodated in the concave portion 4, and positive and negative electrode pads 62 of the light emitting device 6 are respectively connected to the respective terminal portions 71. Then, the phosphor-containing transparent resin 4c is filled in the concave portion 4.

By the above manner, the lamp 1 as shown in FIG. 1 to FIG. 3 is produced.

According to the production method of the lamp 1 mentioned above, the light reflection portion 9 is formed by superposing the covering member 3 on the base board 2, and by mutually joining the base-side joining metal foil 81 and the cover-side joining metal foil 82. Therefore, the lamp 1 can be produced without concern of partial absorption of light emitted from the light emitting device 6.

### Second Embodiment

Hereunder is a description of a second embodiment of the present invention, with reference to the drawings. FIG. 5 is a schematic cross-sectional view showing the principal part of a lamp of the present embodiment. FIG. 5 is for explanatory purposes only, similarly to FIG. 1 to FIG. 3, with respect to the constitution of the lamp of the present embodiment. The size, thickness, dimension, and so forth of the illustrated components may not reflect the actual dimensional relations of the lamp.

In addition, the lamp of the present embodiment is different from the lamp of the first embodiment in the point that a reflective metal film is formed on the end face (light reflection portion) of the metal layer exposed on the lateral surface portion of the concave portion. Accordingly, in the following description, the difference between the present embodiment and the first embodiment is mainly described. Moreover, the same reference symbols are used for components of FIG. 5 which are the same as those of FIG. 1 to FIG. 3.

As shown in FIG. 5, the lamp 11 of the present embodiment schematically comprises a substrate 5 which is integrally composed of a base board (base substrate) 2 and a covering member 3; and a semiconductor light emitting device 6 (hereunder, referred to as a light emitting device). The base board 2 and the covering member 3 are integrated through a metal layer 8. In addition, a concave portion 4 is provided in the substrate 5, and a light emitting device 6 is accommodated in this concave portion 4. Moreover, the base board 2 is exposed on the bottom face 4a of the concave portion 4, and on this exposed base board 2, a pair of wiring patterns 7 made of a copper foil or the like is formed. On these wiring patterns 7, the light emitting device 6 is mounted. Furthermore, in the lateral surface portion 4b of the concave portion 4 is positioned an end face 8a of the metal layer 8 which mutually joins the base board 2 and the covering member 3.

As shown in FIG. 5, this end face 8a is positioned on a region of the lateral surface portion 4b of the concave portion 4 which faces the light emitting device 6. Moreover, over this end face 8a is formed a coating of a light reflective metal film 12 having a thickness of about 3 μm to 5 μm. This light reflective metal film 12 forms the light reflection portion 9. The light reflective metal film 12 is made of a metal presenting a silver white color such as Al, Ag, and Ni, and is coated over the metal layer 8 made of copper presenting a red metal color.

The end face 8a of the metal layer 8 made of copper has metallic luster, and thus has a light reflective function. By further coating this end face 8a with the light reflective metal film 12 presenting a silver white color, light emitted from the light emitting device 6 can be more efficiently reflected.

By so doing, the volume of light emission from the lamp 11 can be further increased.

In order to coat the end face 8a of the metal layer 8 with the light reflective metal film 12, the procedure may be such that, after joining the base board 2 and the covering member 3 by thermocompression bonding in the substrate formation step (FIG. 4C) of the first embodiment, the light reflective metal film 12 is formed by means of a plating method, vapor-deposition method, or the like, over the end face 8a of the metal layer 8 exposed in the concave portion 4, followed by mounting of the light emitting device 6.

### Third Embodiment

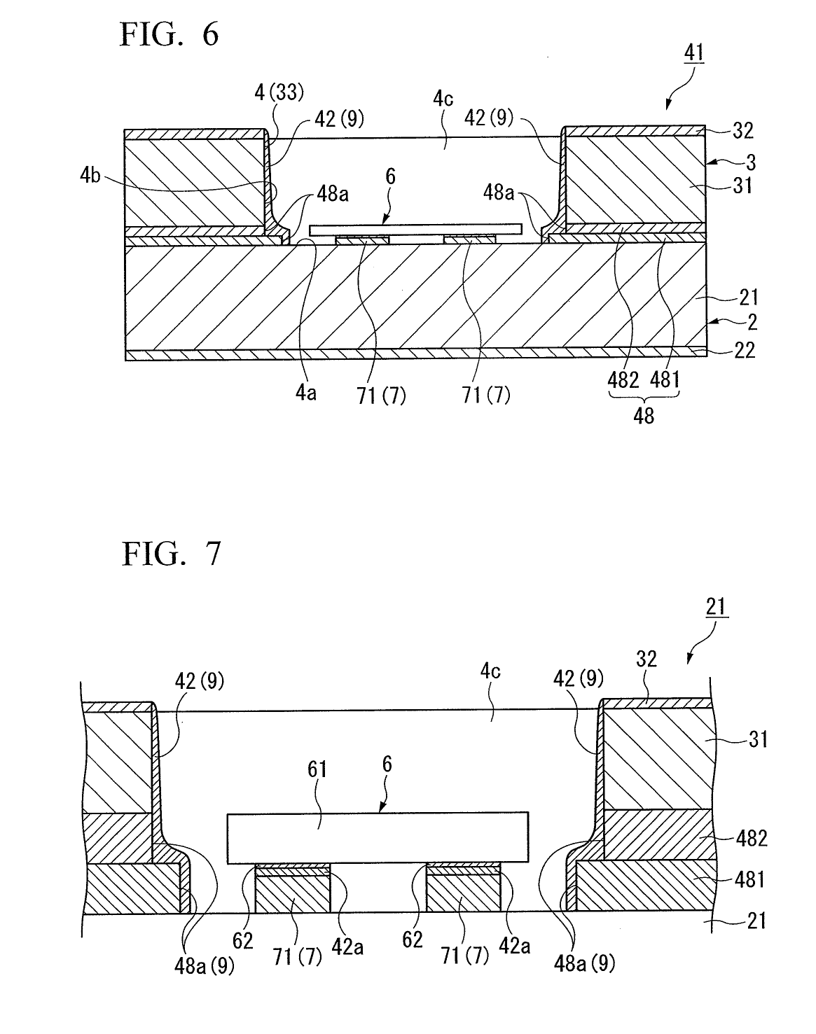

Next is a description of a third embodiment of the present invention, with reference to the drawings. FIG. 6 is a schematic plan view showing a lamp of the present embodiment. FIG. 7 is an enlarged view of FIG. 6. FIG. 6 and FIG. 7 are for explanatory purposes only, similarly to FIG. 1 to FIG. 3, with respect to the constitution of the lamp of the present embodiment. The size, thickness, dimension, and so forth of the illustrated components may not reflect the actual dimensional relations of the lamp.

In addition, the lamp of the present embodiment is different from the lamp of the first embodiment in the point that a light reflective metal film is formed on the lateral surface portion 4b of the concave portion 4 including the end face 8a of the metal layer 8. Accordingly, in the following description, the difference between the present embodiment and the first embodiment is mainly described. Moreover, the same reference symbols are used for components of FIG. 6 and FIG. 7 which are the same as those of FIG. 1 to FIG. 3.

As shown in FIG. 6 and FIG. 7, the lamp 41 of the present embodiment schematically comprises a substrate 5 which is integrally composed of a base board (base substrate) 2 and a covering member 3; and a light emitting device 6. The base board 2 and the covering member 3 are integrated through a metal layer 48. In addition, a concave portion 4 is provided in the substrate 5, and a light emitting device 6 is accommodated in this concave portion 4. Moreover, the base board 2 is exposed on the bottom face 4a of the concave portion 4, and on this exposed base board 2, a pair of wiring patterns 7 made of a copper foil or the like is formed. On these wiring patterns 7, the light emitting device 6 is mounted.

In addition, a joining metal foil 481 is formed on a covering member-side surface 21b of a board main body 21 which constitutes the base board 2.

Furthermore, a cover-side joining metal foil 482 is formed on a region of a base board-side surface 31b of a board main body 31 which constitutes the covering member 3, which encloses the through hole 33.

The metal layer 48 is formed by joining the respective joining metal foils.

Next, on the lateral surface portion 4b of the concave portion 4 is positioned an end face 48a of the metal layer 48 which mutually joins the base board 2 and the covering member 3. Moreover, regarding the end face 48a of the metal layer 48, the end face of the joining metal foil 481 is protruded from the end face of the joining metal foil 482. By so doing, the end face 48a of the metal layer 48 is divided into two surfaces.

As shown in FIG. 6 and FIG. 7, this end face 48a is positioned on a region of the lateral surface portion 4b of the concave portion 4 which faces the light emitting device 6. Moreover, over the lateral surface portion 4b of the concave portion is formed a coating of a light reflective metal film 42 having a thickness of about 3 μm to 5 μm. Similarly to the second embodiment, this light reflective metal film 42 is made of a metal presenting a silver white color such as Al, Ag, and Ni, and is coated over the lateral surface portion 4b made of an inorganic insulator and the metal layer 48 made of copper. In addition, as shown in FIG. 7, between terminal portions 71 of the wiring patterns 7 and electrode pads 62 of the light emitting device 6 is formed a metal film 42a made of a material which is the same as that of the light reflective metal film 42.

The end face 48a of the metal layer 48 made of copper has metallic luster, and thus functions as a light reflection portion. By further coating this end face 48a with the light reflective metal film 42 presenting a silver white color, light emitted from the light emitting device 6 can be more efficiently reflected. Moreover, the lateral surface portion 4b of the concave portion 4 made of an inorganic insulator does not have metallic luster, and thus its light reflective function is relatively low. However, by further coating all over the lateral surface portion 4b with the light reflective metal film 42, light emitted from the light emitting device 6 can be further efficiently reflected.

By so doing, the volume of light emission from the lamp 41 can be further increased.

In order to coat the lateral surface portion 4b of the concave portion and the end face 48a of the metal layer 48 with the light reflective metal film 42, the procedure may be such that, after joining the base board 2 and the covering member 3 by thermocompression bonding in the substrate formation step (FIG. 4C) of the first embodiment, the light reflective metal film 42 is formed by means of a plating method, vapor-deposition method, or the like, over the lateral surface portion 4b of the concave portion 4 and the end face 48a of the metal layer 48, followed by mounting of the light emitting device 6.

At the time of formation of the light reflective metal film 42, metal films 42a made of a material which is the same as that of the light reflective metal film 42 are formed on the terminal portions 71 of the wiring patterns 7, in which case, it is desirable to previously form a lift-off resist or the like between the respective terminal portions 71 so as to prevent the formation of the metal film 42a therebetween. This is for the purpose of prevention of short-circuiting between the terminal portions 71 due to formation of the metal film 42a between the terminal portions 71.

### Fourth Embodiment

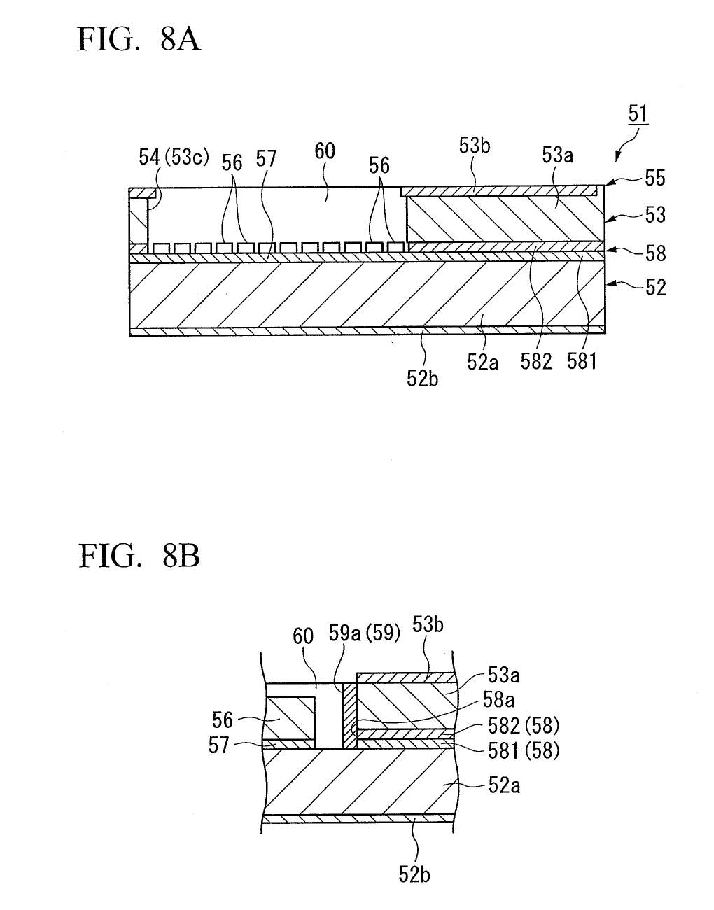

Next is a description of a fourth embodiment of the present invention, with reference to the drawings. FIG. 8A is a schematic cross-sectional view showing a lamp of the present embodiment. FIG. 8B is a schematic cross-sectional view showing the principal part of the lamp.

As shown in FIG. 8, the lamp 51 of the present embodiment schematically comprises a substrate 55 which is integrally composed of a base board (base substrate) 52 mainly made of aluminum oxide, and a covering member 53 mainly made of aluminum oxide; and light emitting devices 56. The base board 52 and the covering member 53 are integrated through a metal layer 58. In addition, a concave portion 54 is provided in the substrate 55, and a plurality of light emitting devices 56 are accommodated in this concave portion 54. In the concave portion 54, twelve light emitting devices 56 are aligned in a row. Moreover, in the bottom face of the concave portion 54 is positioned the base board 52. On this base board 52, a wiring pattern 57 made of copper foil or the like is formed. On this wiring pattern 57, the light emitting devices 56 are mounted. Furthermore, as shown in FIG. 8B, on the lateral surface portion of the concave portion 54 is positioned an end face 58a of the metal layer 58 which mutually joins the base board 52 and the covering member 53. Moreover, on the lateral surface portion of the concave portion 54 is formed a light reflective metal film 59a, and this light reflective metal film 59a constitutes the light reflection portion 59.

The base board 52 which constitutes the substrate 55 comprises a tabular board main body 52a made of aluminum oxide; and a warpage prevention metal foil 52b which is made of copper or the like and is formed on a surface of the board main body 52a which is the opposite side to the wiring pattern 57 side. A wiring pattern 57 to be connected with the light emitting devices 56, and a joining metal foil 581 are formed on a covering member 53-side surface of the board main body 52a. The wiring pattern 57 and the joining metal foil 581 are respectively made of copper foils or the like in a thickness of about 35 to 250 μm.

Next, the covering member 53 comprises a tabular board main body 53a made of aluminum oxide; and a warpage prevention metal foil 53b which is made of copper or the like and is formed on a surface of the board main body 53a which is the opposite side to the base board 52. In addition, a through hole 53c is provided in the board main body 53a.

Furthermore, a cover-side joining metal foil 582 is formed in a region of a base board-side surface of the board main body 53a which encloses the through hole 53c. Similarly to the base-side joining metal foil 581, this cover-side joining metal foil 582 is made of a copper foil or the like in a thickness of about 35 to 250 μm, and is formed in a shape approximately the same as that of the joining metal foil 581.

In addition, as shown in FIG. 8, the abovementioned base board 52 and covering member 53 integrally compose the substrate 55 which constitutes the lamp 51. In a surface of this substrate 55 is formed the concave portion 54 comprising the through hole 53c.

Moreover, between the base board 52 and the covering member 53, the board-side joining metal foil 581 and the cover-side joining metal foil 582 are mutually joined by thermocompression bonding, whereby the metal layer 58 is formed between the base board 52 and the covering member 53. Through this metal layer 58, the base board 52 and the covering member 53 are integrated without an adhesive or a fastener. In addition, the end face 58a of the metal layer 58 is positioned on a region of the lateral surface portion of the concave portion 54 which faces the light emitting devices 56. A light reflective metal film 59a is formed on the lateral surface portion of the concave portion 54 including the end face 58a. This light reflective metal film 59a constitutes the light reflection portion 59.

The light emitting devices 56 are made of, for example, flip-chip type blue light emitting diodes. These light emitting devices 56 are accommodated in the concave portion 54 while being connected to the wiring pattern 57.

As described above, the light reflective metal film 59a is formed on the lateral surface portion of the concave portion 54, and this light reflective metal film 59a constitutes the light reflection portion 59. With this light reflection portion 59, light emitted from the light emitting devices 56 will not be absorbed but can be efficiently ejected to the outside of the concave portion 54.

Furthermore, a yellow phosphor-containing transparent resin 60 is filled in the concave portion 54. By embedding blue light emitting diodes (light emitting devices 56) in this yellow phosphor-containing transparent resin 60, white light can be emitted due to the additive color effect of light when the blue light emitting diodes are lit.

According to the lamp 51 mentioned above, substantially the same effect as that of the lamp 41 of the third embodiment can be obtained.

### Fifth Embodiment

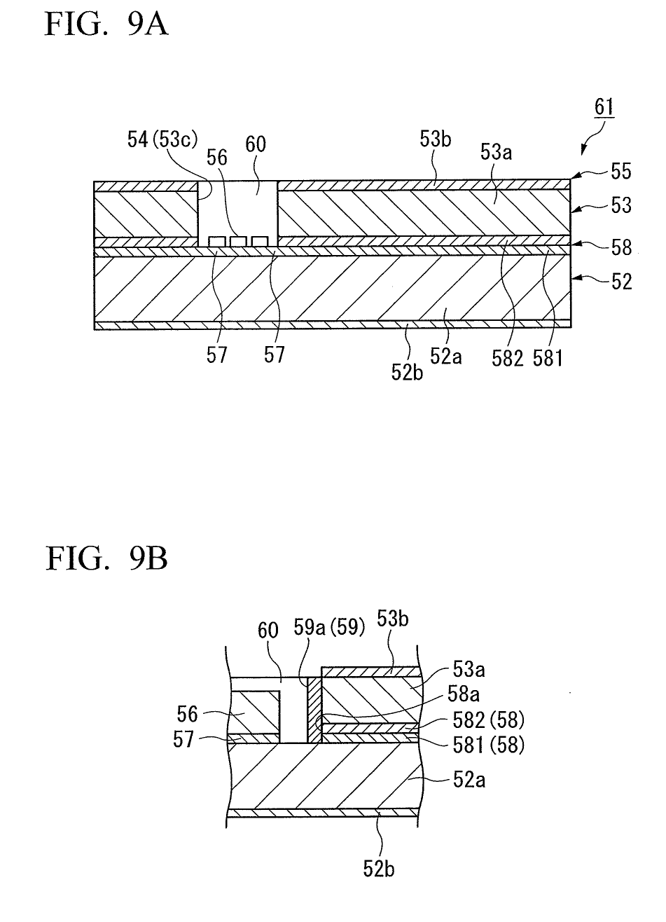

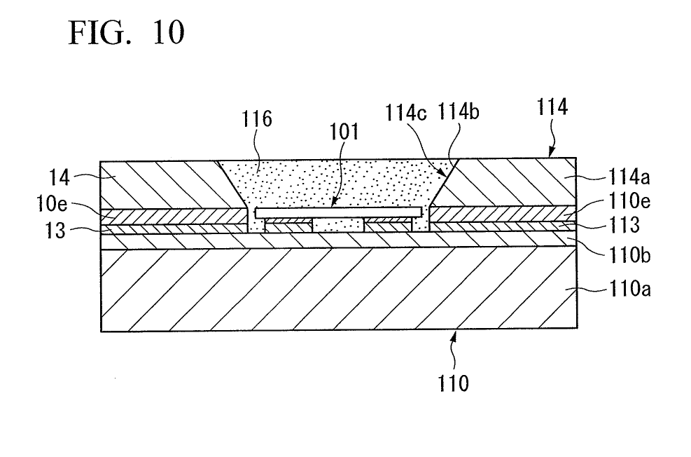

FIG. 9A is a schematic cross-sectional view showing a lamp of a fifth embodiment. FIG. 9B is a schematic cross-sectional view showing the principal part of the lamp.

The lamp 61 of the present embodiment is different from the lamp 51 of the fourth embodiment in the point that six light emitting devices are aligned in three rows×two columns in the concave portion. The other constitution is substantially the same as that of the fourth embodiment.

Therefore, according to the lamp 61 mentioned above, substantially the same effect as that of the lamp 41 of the third embodiment can be obtained.

1. A lamp comprising a substrate composed of a base substrate and a covering member which are made of an inorganic insulator and are joined through a joining metal layer; and a semiconductor light emitting device mounted on said substrate, wherein
a concave portion is provided in a covering member-side surface of said substrate,
said semiconductor light emitting device is accommodated in said concave portion,
an end face of said metal layer is positioned on a region of the lateral surface of said concave portion which faces said semiconductor light emitting device, and
a light reflection portion, which reflects light emitted from said semiconductor light emitting device, is composed of said end face.

2. The lamp according to claim 1, wherein a light reflective metal film is formed on the end face of said metal layer.

3. The lamp according to claim 1, wherein a light reflective metal film is formed on the lateral surface of said concave portion including the end face of said metal layer.

4. The lamp according to claim 1, wherein
said covering member is provided with a through hole which constitutes said concave portion,
a cover-side joining metal foil is formed around said through hole on a base substrate-side surface of said covering member,
a base-side joining metal foil to be superposed with said cover-side joining metal foil is formed on said covering member-side surface of said base substrate, and
said metal layer is formed by mutually joining said respective joining metal foils.

5. The lamp according to claim 4, wherein said base substrate and said covering member are made of aluminum oxide, and said respective joining metal foils are made of copper.

6. The lamp according to claim 1, wherein a phosphor-containing transparent resin is filled in said concave portion.

7. The lamp according to claim 1, wherein said semiconductor light emitting device is a flip-chip type light emitting diode.

8. A production method of a lamp, comprising:
a covering member formation step for providing a through hole in a tabular inorganic insulator, and forming a cover-side joining metal foil around said through hole on a surface of said inorganic insulator;
a base substrate formation step for forming a base-side joining metal foil to be superposed with said cover-side joining metal foil, on a surface of a base substrate made of an inorganic insulator;
a substrate formation step for superposing said covering member on said base substrate and joining them by thermocompression bonding, to thereby close an opening at one end of said through hole by said base substrate to form a concave portion, as well as forming a metal layer by mutually joining said respective joining metal foils, and disposing an end face of this metal layer on the lateral surface of said concave portion to serve as a light reflection portion; and
a mounting step for accommodating a semiconductor light emitting device in said concave portion while arranging the light emitting device to face said light reflection portion.

9. The production method of a lamp according to claim 8, wherein the thermocompression bonding is performed by heating said base substrate and said covering member to 1000° C. or higher, in said substrate formation step.

10. The production method of a lamp according to claim 8, wherein a light reflective metal film is formed on at least an end face of said metal layer, after said substrate formation step.
